(19) United States
(12) Patent Application Publication
(10) Pub. No.: US 2004/0178480 A1
(43) Pub. Date: Sep. 16, 2004

(54) Semiconductor device and method of manufacturing the same

(76) Inventors: Masato Koyama, Miura-gun (JP); Akira Nishiyama, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/726,705

(22) Filed: Dec. 4, 2003

(30) Foreign Application Priority Data
Dec. 6, 2002 (JP) 2002-355451

(51) Int. Cl. H01L 23/58

(52) U.S. Cl. 257/632

(57) ABSTRACT

Disclosed is a semiconductor device comprising a substrate, an insulating film formed on the surface of the substrate, and an electrode formed on the insulating film. The substrate side of the insulating film is formed of an epitaxial crystalline insulating layer containing metal, silicon and oxygen, and the electrode side of the insulating film is formed of an amorphous insulating layer additionally containing nitrogen.

### CROSS-REFERENCE TO RELATED APPLICATIONS

This application is based upon and claims the benefit of priority from the prior Japanese Patent Application No. 2002-355451, filed Dec. 6, 2002, the entire contents of which are incorporated herein by reference.

### BACKGROUND OF THE INVENTION

1. Field of the Invention

This invention relates to a semiconductor device and the manufacturing method thereof, and in particular, to a semiconductor device having an MIS field effect transistor (MISFET) incorporated therein and the manufacturing method thereof.

2. Description of the Related Art

In a CMOS (Complementary Metal-Oxide Semiconductor) device of sub-0.1 μm generation, the gate insulating film thereof is required to have such properties as corresponding to an SiO₂ film having a thickness of 1.5 nm or less. However, if the SiO₂ film is made as thin as 1.5 nm, the SiO₂ film which has been conventionally employed as a gate insulating material is no longer capable of acting as an insulating film but behaves like a conductive material due to the direct tunneling current transport. Since the remarkable deterioration of insulating property of the SiO₂ film due to the extreme thinning thereof would lead to an increase in power consumption, the practical utilization of an SiO₂ film as a gate insulating film in future semiconductor devices is considered as impossible.

Under the circumstances, many efforts are now being made for developing the technique of so-called High-κ gate insulating film, which makes it possible to increase the physical thickness of the insulating film through the utilization of a material exhibiting a higher relative permittivity (High-κ material) than that of SiO₂, thereby making it to decrease the EOT (equivalent oxide (SiO₂) thickness) while reducing the leakage current.

In particular, in the case of an advanced semiconductor device of 50 nm node which is aimed at in the future technology of around the year 2007, a High-κ gate insulating film having a property corresponding to an SiO₂ film having a thickness of less than 1.0 nm (i.e. an EOT of less than 1.0 nm) will be required. In the case of a representative High-κ material which is now being studied (HfO₂, Al₂O₃, etc.), the formation of an interface layer is deemed imperative in order to improve the interface characteristics thereof with an Si substrate.

With a view to overcome the above problems, there has been developed a so-called epi-High-κ insulating film (epitaxial High-κ gate insulator(s)) technique wherein High-κ material is directly contacted with an Si substrate. It is reported that excellent interface characteristics can be obtained through the employment of the epi-High-κ material without necessitating the provision of an interface layer, thereby making it possible to greatly reduce the EOT. For example, an insulating film having an EOT of 0.38 nm is realized in an MIS capacitor where CeO₂ having a relative permittivity of 50 or so is epitaxially grown on an Si substrate.

A High-κ gate insulating film which has been epitaxially grown directly on the surface of an Si substrate is known to exhibit very excellent interface electric characteristics. For example, it is known that an MIS transistor having an SrTiO/Si type epitaxial layer is capable of exhibiting an interfacial electron mobility which is almost equivalent to that of ideal SiO₂ film.

Even though the epi-High-κ material is excellent in performance, the epi-High-κ material is accompanied with a problem with regard to the thermal stability thereof. For example, an epi-High-κ/Si type layer is in most cases vulnerable to high-temperature annealing to be performed in the LSI manufacturing process, thereby allowing the epitaxial structure thereof to be destroyed due to the annealing. Further, since the epi-High-κ material is formed of a crystallized body, it is very high in transparency to the diffusion of impurities, thereby giving rise, for example, to the diffusion of impurities from the gate electrode or to the diffusion of metal elements constituting the gate electrode. In that case, there are much possibilities that the active region of MISFET is seriously damaged.

It should be noted that there is also proposed a method wherein nitrogen atom is added to a non-epiaxial High-κ material to keep the High-κ insulating film in an amorphous state as a whole.

As explained above, if an epi-High-κ gate insulating film is to be deposited according to the conventional method on an Si layer employed as a substrate, it is required to perform the deposition at a temperature which is much lower than the high-temperature process employed in the formation of the LSI. Thus, the epi-High-κ insulating film is accompanied with a serious problem with respect to thermal stability.

The epi-High-κ insulating film has excellent properties suitable for employment in an advanced CMOS device in future. However, unless the fundamental problems such as thermal instability and poor resistance in impurity diffusion are overcome, there is a very little possibility that the epi-High-κ insulating film can be actually used in a semiconductor device.

The present invention has been made in view of overcoming the aforementioned problems, and therefore, it is an object of the present invention to provide a semiconductor device provided with a High-κ insulating film which is improved not only in thermal stability but also in impurity diffusion resistance while making it possible to reduce the EOT of epi-High-κ insulating film and to retain the excellent interfacial properties thereof. Another object of the present invention is to provide a method of manufacturing such a semiconductor device.

### BRIEF SUMMARY OF THE INVENTION

According to one embodiment of the present invention, there is provided a semiconductor device comprising: a substrate; an insulating film formed on the substrate, the insulating film being constituted by a substrate-side layer which is formed of an epitaxial crystalline insulating layer containing a metal, silicon and oxygen, and by an electrode-side layer which is formed of an amorphous insulating layer containing a metal, silicon, oxygen and nitrogen; and an electrode formed on the insulating film.

According to other embodiment of the present invention, there is provided a method of manufacturing a semiconductor device comprising: forming an amorphous insulating layer containing a metal, silicon and oxygen on a substrate, the amorphous insulating layer further containing nitrogen in a surface region thereof; and heat-treating the amorphous insulating layer in a non-oxidizing atmosphere, permitting a solid-phase growth to take place in a region containing no nitrogen while remaining the nitrogen-containing surface region as an amorphous insulating layer, thereby forming an epitaxial crystalline insulating layer containing a metal, silicon and oxygen on the substrate side of the amorphous insulating layer.

According to other embodiment of the present invention, there is provided a method of manufacturing a semiconductor device comprising: forming an amorphous insulating layer containing metal, silicon and oxygen on a substrate, the amorphous insulating layer comprising a surface region and a remnant region, the surface region further containing a nitrogen of a first concentration, and the remnant region containing a nitrogen of a second concentration less than the first concentration; and heat-treating the amorphous insulating layer in a non-oxidizing atmosphere, permitting a solid-phase growth to take place in the remnant region while having the first region as an amorphous insulating layer.

### BRIEF DESCRIPTION OF THE SEVERAL VIEWS OF THE DRAWING

FIG. 1 is a cross-sectional TEM (Transmission Electron Microscope) photograph illustrating one example of an epitaxial High-κ insulating layer of the insulating film according to one embodiment of the present invention;

FIG. 2 is a cross-sectional TEM photograph illustrating another example of an epitaxial High-κ insulating layer in the insulating film according to another embodiment of the present invention;

FIG. 3 is a cross-sectional TEM photograph illustrating the conventional insulating film which has been heat-treated;

FIGS. 4A to 4C respectively show a cross-sectional view illustrating the steps of forming an insulating film according to one embodiment of the present invention;

FIG. 5 is a cross-sectional TEM photograph illustrating another example of an epitaxial High-κ insulating layer in the insulating film according to another embodiment of the present invention;

FIG. 6 is a graph illustrating the capacitance-voltage characteristics of an insulating film according to another embodiment of the present invention;

FIG. 7 is a graph illustrating the current-voltage characteristics of an insulating film according to another embodiment of the present invention;

FIG. 8 is a graph illustrating the results of SIMS analyzing experiments of insulating film; and

FIG. 9 is a cross-sectional view schematically illustrating the semiconductor device according to one embodiment of the present invention.

### DETAILED DESCRIPTION OF THE INVENTION

Next, specific embodiments of the present invention will be explained with reference to drawings.

The insulating film to be employed in a semi-conductor device according to the embodiments of the present invention is featured in that the substrate-side thereof differs in characteristics from the electrode-side thereof. More specifically, the substrate-side of the insulating film is constituted by an epitaxial crystalline insulating layer containing metal, silicon and oxygen, and the electrode-side of the insulating film is constituted by an amorphous insulating layer which contains nitrogen atoms in addition to metal, silicon and oxygen. In particular, the epitaxial crystalline insulating layer constituting the substrate-side of the insulating film was formed through the solid phase growth thereof which was executed by the high-temperature annealing of an amorphous High-κ layer/Si structure.

First of all, it was confirmed by the present inventors that a crystalline High-κ layer could be epitaxially grown through the solid phase growth thereof that could be executed by the high-temperature annealing of an amorphous High-κ layer/Si structure.

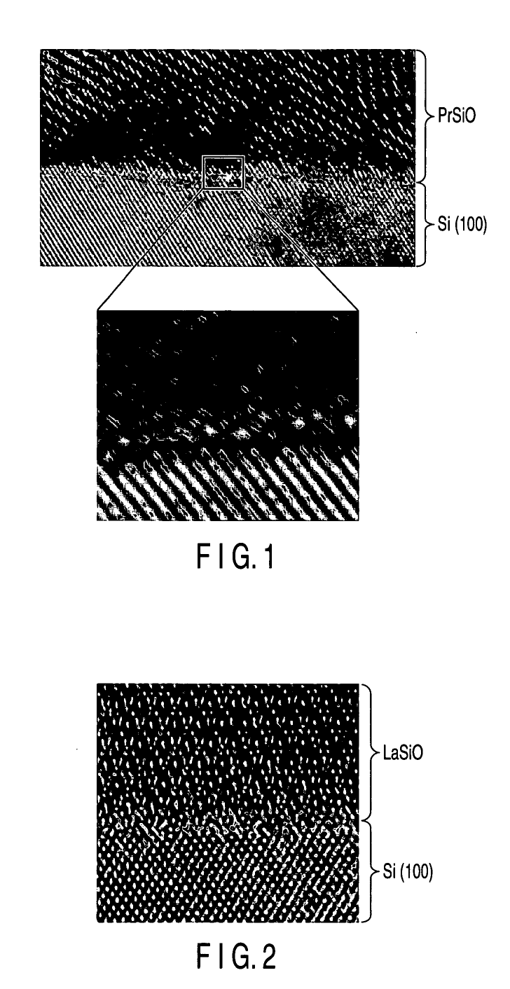

For example, an amorphous PrSiₓO_{y} layer was deposited on the surface of an Si substrate to a thickness of 10 nm by sputtering method, and then, a polycrystalline Si layer was deposited on the amorphous layer to a thickness of 200 nm by a CVD method. Thereafter, the resultant body was heat-treated for 30 seconds at a temperature of 1000° C. in a nitrogen gas atmosphere. FIG. 1 shows a TEM photograph of the cross-section of the structure obtained in this manner.

As apparent from the photograph of FIG. 1, a crystalline insulating layer having a thickness of 10 nm or so was epitaxially grown on the surface of the Si (100) substrate. It was confirmed, through the component analysis of the cross-section of a sample by EDX (Energy Dispersive X-ray Spectrometer), that the crystalline insulating layer that had been epitaxially grown was constituted by PrSiₓO_{y}.

Then, in the same manner as described above, an amorphous LaSiₓO_{y} layer and polycrystalline Si layer were successively formed. The film thickness of each of these layers was 10 nm and 100 nm, respectively. Then, the structure thus obtained was heat-treated for 30 seconds at a temperature of 1000° C. in a nitrogen atmosphere, the cross-section of resultant structure being shown as a TEM photograph in FIG. 2. The TEM photograph indicates that in the same manner as in the case of the aforementioned amorphous PrSiₓO_{y}, it was possible to epitaxially grow, by solid growth, a crystalline insulating film having a thickness of about 10 nm on the surface of the Si (100) substrate.

In any of the aforementioned processes of epitaxial growth, since crystalline insulating films were formed through a solid phase growth at a high temperature of 1000° C., it can be said that the resultant structure was capable of withstanding the impurity-activating process of the LSI. Further, since the solid phase growth was permitted to take place at a high temperature of 1000° C., the resultant structure was found very stable from a thermodynamic viewpoint. The interfacial structure of the epi-High-κ insulating film/Si that has been formed at such a high temperature would be capable of retaining sufficient stability even if the interfacial structure is subjected to the subsequent high-temperature process of the LSI. Since the high-temperature process of an LSI is assumably performed at a temperature ranging from 950° C. to 1200° C. in general, the heat treatment for effecting the solid phase growth of a crystalline insulating film should preferably be performed a temperature falling within this range.

On the occasion of realizing the solid phase growth in a high-temperature process, there is much possibility of generating the oxidation of an Si substrate due to the diffusion of oxygen originating from the atmosphere surrounding the device if the amorphous layer/Si substrate structure is exposed to the atmosphere as it is. In order to avoid the oxidation of an Si substrate, the high-temperature annealing for the solid phase growth should preferably be performed in an atmosphere comprising a partial oxygen pressure of 1×10⁻³ Torr or less. Alternatively, the oxidation of the surface of the Si substrate may be prevented by depositing a conductive film to be utilized as an electrode on the surface of the amorphous insulating layer prior to the high-temperature annealing.

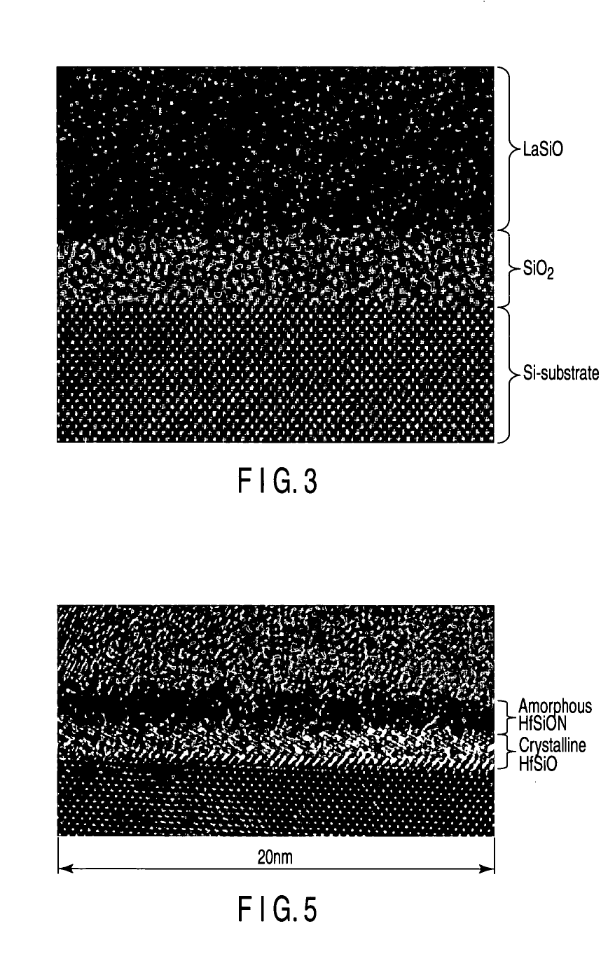

In this connection, an amorphous LaSiₓO_{y} layer having a thickness of 10 nm was formed on the surface of the Si substrate according to the same method as described above, and then, the resultant body was heat-treated, without preliminarily forming a conductive film on the surface of the amorphous layer, for 30 seconds at a temperature of 1000° C. in an atmosphere comprising a partial oxygen pressure of 1×10⁻² Torr. A TEM photograph of the cross-section of the resultant structure is shown in FIG. 3.

It will be clearly recognized from the photograph of FIG. 3 that an interfacial layer consisting of SiO₂, instead of a crystalline layer to be formed through a solid phase growth, has been formed between the Si substrate and the LaSiₓO_{y} layer. This suggests that the process of oxidizing the surface of the Si substrate by oxygen molecule that has been diffused into the surface of the Si substrate from the heat-treating atmosphere was competing with the process of the epitaxial growth of the crystalline insulating layer. Namely, if the SiO₂ interface layer is allowed to grow as the oxidation reaction becomes dominant, the growth of epitaxial solid phase would be suppressed.

It has been confirmed that when an amorphous insulating layer is heat-treated in a non-oxidizing atmosphere, it is theoretically possible to allow the solid phase growth of an epi-High-κ crystalline insulating layer excellent in thermal stability to take place on the surface of the Si substrate while suppressing the growth of an SiO₂ interface layer.

Although the epi-High-κ crystalline insulating layer is excellent in thermal stability, the epi-High-κ crystalline insulating layer is defective in that the transparency thereof to the impurity diffusion is extremely high. Therefore, in order to improve the impurity diffusion resistance of the epi-High-κ crystalline insulating layer by effectively preventing the diffusion of impurities or metal elements into the epi-High-κ crystalline insulating layer from the electrode side thereof, the electrode side of the epi-High-κ crystalline insulating layer is kept to remain in an amorphous state in the embodiments of the present invention. This countermeasure is made possible, in the present invention, through the inclusion of nitrogen into the surface region of the High-κ insulating layer prior to the heat treatment. By enhancing the impurity diffusion resistance of the epi-High-κ crystalline insulating layer, it is possible to prevent the active region from being contaminated with impurities in the case of MISFET for example.

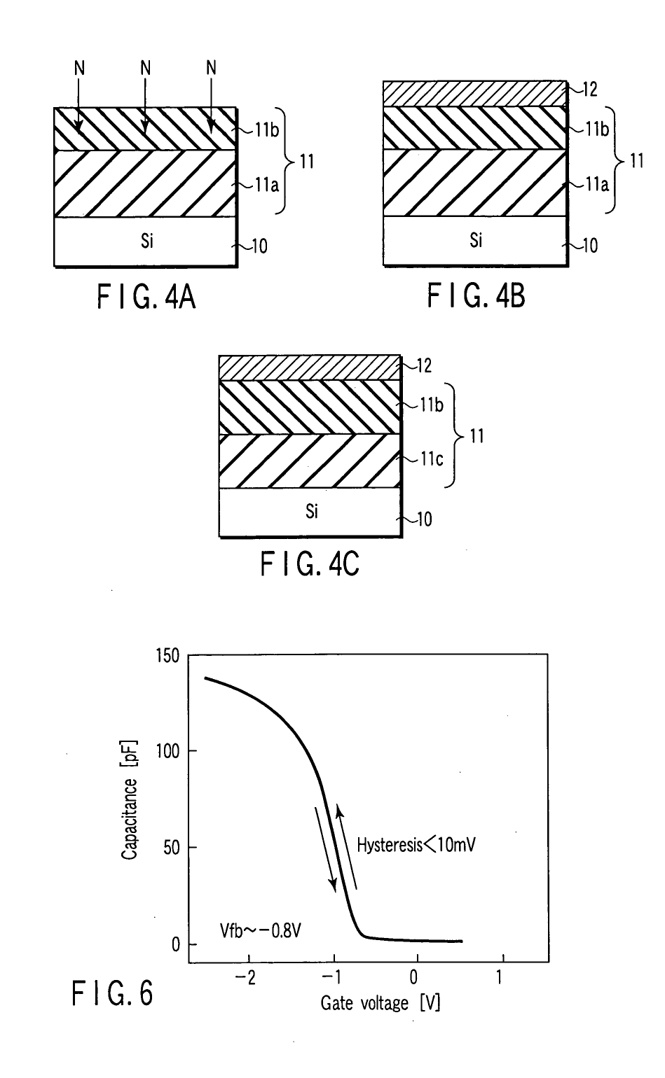

Next, one example of manufacturing method of such an insulating film as mentioned above will be explained with reference to FIGS. 4A to 4C.

First of all, as shown in FIG. 4A, an amorphous High-κ insulating layer is deposited on the surface of an Si substrate 10. As for the specific materials to be employed in the amorphous High-κ insulating layer, they include oxides or silicates containing a lanthanoid metal such as La, Ce, Pr, Nd, Pm, Sm, Eu, Gd, Tb, Dy, Ho, Er, Tm, Yb and Lu; or oxides or silicates containing Hf, Zr, Ti, etc. In this case, there is not any particular limitation with regard to the method of forming the layer, and therefore, it is possible to employ a CVD method, a sputtering method, an MBE method, a metal post oxidizing method, etc.

Then, the surface of the amorphous High-κ insulating layer is exposed to nitrogen of excited state to permit the nitrogen to enter into the amorphous High-κ insulating layer from the surface thereof to a predetermined depth, thereby forming a nitrogen-containing region 11b. More specifically, nitrogen can be incorporated into the amorphous High-κ insulating layer by plasma nitridation, remote plasma nitridation, etc. The nitrogen-containing region 11b is capable of obstructing the epitaxial growth of the High-κ insulating layer, thereby preventing the solid phase growth of the High-κ insulating layer from further proceeding beyond the nitrogen-containing region 11b. Namely, when the resultant body is subsequently heat-treated in a non-oxidizing atmosphere, only the nitrogen-free region 11a is permitted to undergo the solid phase growth thereof, thus forming the epi-High-κ insulating layer.

In order to enable the effect of adding nitrogen to be secured sufficiently, the concentration of nitrogen to be incorporated in the insulating film should preferably be set to 15 atom % or more. If the concentration of nitrogen is less than 15 atom %, the film may possibly be crystallized in the process of high-temperature treatment of 1000° C. or so while failing to sufficiently obtain the effect of adding nitrogen, thereby making it impossible to realize a distinct laminate structure of High-κ amorphous layer/epi-High-κ crystalline layer.

Further, the thickness of nitrogen-containing region 11b should preferably be within the range of 1 nm to 2.5 nm. If the thickness of nitrogen-containing region 11b is less than 1 nm, the impurities may be permitted to diffuse into the amorphous layer, thus making it difficult to effectively suppress the diffusion of impurities. On the other hand, if the thickness of nitrogen-containing region 11b exceeds over 2.5 nm, the EOT may become larger, thereby making it impossible to satisfy the requirements desired of gate insulating film.

The amorphous High-κ insulating layer 11 having the nitrogen-containing region 11b can be formed in such a manner that, first of all, a metal silicate layer is deposited on the substrate in an atmosphere which is free from nitrogen gas, and then, the atmosphere is purged with nitrogen gas. If Hf silicate is to be deposited as metal silicate, an amorphous High-κ insulating layer containing no nitrogen is deposited on the substrate by sputtering method, etc. in an Ar/O₂ atmosphere for instance. Thereafter, a nitrogen-containing region is deposited in an Ar/O₂/N₂ atmosphere having a nitrogen partial pressure ranging from 1/20 to 1/10 based on the total pressure, thereby forming the amorphous High-κ insulating layer 11 having the nitrogen-containing region 11b on the surface thereof as described above.

Subsequently, in order to secure a non-oxidizing atmosphere, a polycrystalline Si film 12 to be employed as an electrode is deposited as shown in FIG. 4B. As already explained above, if the heat treatment is to be performed in an atmosphere comprising an oxygen partial pressure of 1×10⁻³ Torr or less, a non-oxidizing atmosphere can be derived therefrom, so that the deposition of the polycrystalline Si film 12 would be no longer required.

Further, the resultant body is subjected to a heat treatment for a period ranging from one second to 30 minutes at a temperature ranging from 950° C. to 1200° C., thereby allowing only the nitrogen-free region 11a to take place a solid phase reaction to obtain an amorphous High-κ insulating layer 11b/a crystalline High-κ insulating layer 11c/Si structure 10. In this case, the period of the heat treatment should preferably be more or less longer such as 30 minutes in view of completely accomplishing the solid phase growth. Further, if it is desired to reduce the manufacturing steps of LSI as much as possible, the solid phase growth may be performed simultaneous with the impurity activating step. In this case, although the heat treatment will be finished taking only one second or so, the solid phase growth can be almost completely accomplished even with this short period of heat treatment.

By using a Hf silicate (HfSiₓO_{y}) as the amorphous High-κ insulating layer 11 and by following the aforementioned process, an amorphous High-κ insulating layer/a crystalline High-κ insulating layer/Si structure was formed. FIG. 5 shows a cross-sectional view of the structure thus obtained. As clearly seen from the photograph of FIG. 5, a Hf silicate (crystalline HfSiO) was found formed through a solid phase epitaxial growth. Specifically, it will be recognized that the crystalline layer was stopped growing at a level in the vicinity of the central region of the nitrogen-incorporated layer, an upper half portion of the insulating film being formed of an amorphous layer (amorphous HfSiON layer). More specifically, the thickness of the amorphous layer was 2 nm or so.

Further, the size of the single crystal in the crystalline layer was confirmed as being 100 nm or so. Thus, the size of single crystal in the crystalline insulating layer formed by solid phase growth is typically 100 nm or more, thus having a larger crystalline region than the length of the gate of future MISFET. This means that the crystalline insulating film included in a single transistor would be constituted by a single crystal. The monocrystalline insulating film to be obtained in this manner is extremely scarce in crystal defects as compared with an amorphous insulating film or a polycrystalline insulating film. Since the long term reliability of semiconductor device is influenced by microscopic crystal defects in the insulating film, it will be suggested that the structure according to this embodiment of the present invention would exhibit excellent performance.

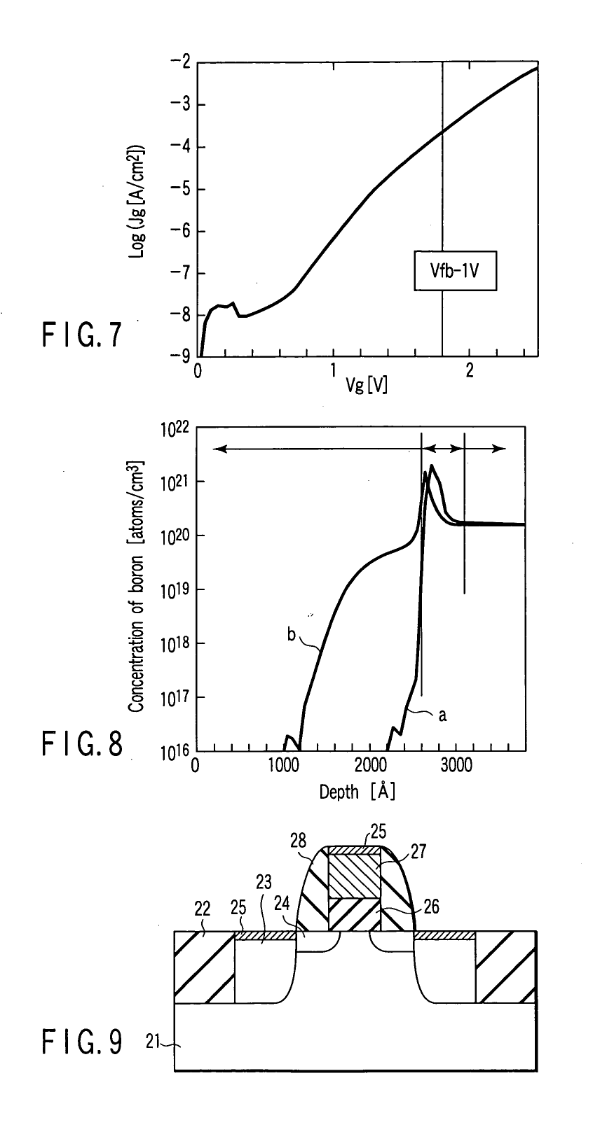

Investigations were performed with respect to the CV characteristics and IV characteristics of the MIS capacitor having an n⁺-polycrystalline Si gate/an amorphous High-κ insulating layer/a crystalline High-κ insulating layer/Si structure shown in FIG. 5, the results obtained being shown in FIGS. 6 and 7, respectively.

As shown in FIG. 6, the V_{fb} (flat band voltage) thereof was found −0.8V or so and the hysteresis thereof was less than 10 mV. As seen from these results, the epi-High-κ/Si substrate interface shown in FIG. 5 apparently exhibited ideal electric characteristics, and the epitaxial interface obtained by the solid phase growth was excellent in quality.

Further, as shown in FIG. 7, the epi-High-κ/Si substrate structure shown in FIG. 5 was very low in leakage current. More specifically, the leakage current of the epi-High-κ/Si substrate structure was capable of reducing the leakage current by three orders of magnitude as compared with the conventional SiO₂ film.

Furthermore, the insulating film having an amorphous region on the surface region thereof as shown in FIG. 5 was investigated with regard to the resistance thereof to the diffusion of impurities from polycrystalline Si. More specifically, the boron impurity that had been incorporated in advance into the polycrystalline Si at a high concentration was permitted to penetrate through the insulating film into the Si substrate, and the concentration of the boron impurity that was penetrated into the Si substrate was measured. The data of experiment of backside SIMS (secondary ion mass spectroscopy) are shown in the graph of FIG. 8 as a curve “a”. The curve “b” shown in FIG. 8 represents the results obtained from an insulating film having no amorphous region.

Since boron is one of the elements which are small in atomic radius and the highest in diffusion velocity inside a substance, the diffusion resistance of boron can be employed as an excellent criterion in estimating the diffusion resistance of the substance to other impurities.

In the graph shown in FIG. 8, the region located 2600 angstroms or less in depth is constituted by the Si substrate, the region located between 2600 to 3000 angstroms in depth is constituted by the insulating film, and the region located below 3000 angstroms or more in depth is constituted by the polycrystalline Si. The abscissa of the graph is graduated based on the etching rate of Si. Since the etching rate in the region of the insulating film would be lowered to 1/10 or less, the actual thickness of the insulating film would be 30 angstroms or so. In the case of the structure according to the embodiment of the present invention where an amorphous portion was provided in a surface region of the insulating film, the diffusion of boron into the Si substrate could be scarcely recognized as shown by the curve “a”.

Whereas, in a structure where the insulating film was entirely crystallized, a prominent degree of diffusion of boron into the Si substrate was recognized as shown by the curve “b”. These facts suggest that when the insulating film is entirely crystallized, the crystal boundaries of this crystallized insulating film would be turned into paths of high-velocity diffusion for impurities, and that when an amorphous film is existed in this case, it is possible to effectively close these high-velocity diffusion paths.

It should be noted that on the occasion of securing an amorphous portion in the surface region of the High-κ insulating layer by the addition of nitrogen thereto, the thickness of the final amorphous High-κ layer is determined by the depth of the nitrogen-incorporated region. Therefore, it is most preferable to perform the nitridation by using a surface-nitridation method using excited nitrogen which is excellent in controllability. The above-mentioned desirable effect can be obtained also by a method wherein a nitrogen-free High-κ layer and a nitrogen-containing High-κ layer are successively deposited while controlling the thickness thereof to obtain an amorphous insulating layer, which is subsequently annealed in a non-oxidizing atmosphere.

The specific embodiments of the present invention have been explained with reference to examples where a rare earth material such as Pr or La, as well as an silicate of transitional metals such as Hf were employed. However, the present invention would never be limited to these specific examples. Namely, almost the same effects as mentioned above would be achieved even if other rare earth metals or other transitional metals such as Zr and Ti are employed, wherein the metal silicate may be replaced by a metal oxide containing no silicon.

The structure comprising an amorphous insulating layer/a crystalline insulating layer (epi-High-κ)/Si according to one embodiment of the present invention is capable of reducing the EOT, thus substantially retaining the advantages of the conventional epi-High-κ material in that respect. In the case of the High-κ gate insulating film other than the conventional epi-High-κ material, it is required, in order to improve the interface characteristics thereof with respect to an Si substrate, to incorporate a material layer having low relative dielectric constant such as SiO₂ into a laminate body, thus rendering the entire EOT to be influenced by this layer of low relative dielectric constant.

Whereas, according to the embodiment of the present invention, the amorphous insulating film has a relatively high relative dielectric constant, and the SiO₂-reduced film thickness of the laminate is permitted to remain smaller. The reason for enabling the amorphous insulating layer to have a relatively high value in relative dielectric constant in this embodiment of the present invention can be attributed to the fact that the amorphous insulating layer is formed of a High-κ material having nitrogen atom incorporated therein.

The insulating film of the present invention wherein the substrate side thereof is constituted by epitaxial crystal and the electrode side thereof is constituted by an amorphous material can be suitably employed as a gate insulating film of an MISFET. FIG. 9 illustrates a cross-sectional view of a semiconductor device having the MISFET incorporated therein according to one embodiment of the present invention.

In this semiconductor device shown in FIG. 9, a gate electrode 27 is disposed via a gate insulating film 26 on a substrate 21 having an element-isolating insulating layer 22 formed therein. As for the substrate 21, it is possible to employ a substrate made of at least either Si or Ge. In this embodiment, a silicon substrate is employed. On both sides of the gate insulating film 26, there are formed source/drain diffusion regions 24 consisting of an impurity diffusion region containing a high concentration of the impurity, thereby constructing an MOS transistor.

The gate insulating film 26 is constructed as mentioned above such that the substrate 21 side thereof is constituted by epi-High-κ crystalline layer comprising single crystal having a dimension shorter than the length of the gate. On the other hand, the gate electrode 27 side of the gate insulating film 26 is constituted by an amorphous layer. The gate insulating film 26 of this structure can be created according to the aforementioned method. Specifically, the gate electrode 27 is deposited on the surface of the gate insulating film 26 by using the conventional methods. For example, the gate electrode 27 can be formed through the deposition of polycrystalline Si or polycrystalline SiGe by using a vacuum CVD method or through the deposition of a high melting point metal nitride such as TiN by using a CVD method.

Then, the gate electrode 27 and the gate insulating film 26 are worked according to the conventional method, which is followed by the formation of shallow junctions 24, gate sidewalls 28, deep junctions 23 and salicide (self-aligned silicide) 25, thus obtaining a semiconductor device as shown in FIG. 9.

Since the substrate side of the gate insulating film 26 is constituted by epi-High-κ crystalline layer, the gate insulating film 26 is excellent in thermal stability, and additionally, since the gate electrode 27 side thereof is constituted by an amorphous layer, the resistance of the gate insulating film 26 against the impurity diffusion is also excellent. Still more, it is possible not only to sufficiently reduce the EOT of the gate insulating film 26 but also to secure excellent interface characteristics between the gate insulating film 26 and the Si substrate 21. As explained above, it is now possible to overcome all of the aforementioned problems accompanied with the conventional device while making it possible to retain the advantages of conventional High-κ insulating layer.

The aforementioned epi-High-κ crystalline layer/amorphous insulating layer structure can be employed as a capacitor insulating film, enabling to obtain the effect of minimizing the leakage current in this case.

As explained above, it is possible, according to the present invention, to provide a semiconductor device provided with a High-κ insulating film which is improved not only in thermal stability but also in impurity diffusion resistance while making it possible to reduce the EOT of epi-High-κ insulating film and to retain the excellent interfacial properties thereof. It is also possible, according to the present invention, to provide a method of manufacturing such a semiconductor device.

The present invention makes it possible to realize an epi-High-κ insulating layer exhibiting excellent characteristics, which would contribute to the realization of an advanced silicon CMOS device which is excellent in operating velocity and low in power consumption, thus rendering the present invention very valuable in industrial viewpoints.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a substrate;
an insulating film formed on the substrate, the insulating film comprising a substrate-side layer of an epitaxial crystalline insulating material and an electrode-side layer of an amorphous insulating material, the epitaxial crystalline insulating material containing metal, silicon and oxygen, and the amorphous insulating material containing metal, silicon, oxygen and nitrogen; and
an electrode formed on the insulating film.

2. The semiconductor device according to claim 1, wherein the nitrogen contained in the amorphous insulating material has a concentration of 15 atom % or more.

3. The semiconductor device according to claim 2, wherein the metal includes at least one element selected from the group consisting of Zr, Hf, Ti and lanthanoid elements.

4. The semiconductor device according to claim 2, wherein the substrate includes source/drain regions, the insulating film is a gate insulating film interposed between the source/drain regions, and the electrode is a gate electrode.

5. The semiconductor device according to claim 1, wherein the metal includes at least one element selected from the group consisting of Zr, Hf, Ti and lanthanoid elements.

6. The semiconductor device according to claim 1, wherein the substrate includes source/drain regions, the insulating film is a gate insulating film interposed between the source/drain regions, and the electrode is a gate electrode.

7. A method of manufacturing a semiconductor device comprising:
forming an amorphous insulating layer containing metal, silicon and oxygen on a substrate, the amorphous insulating layer further containing nitrogen in a surface region thereof; and
heat-treating the amorphous insulating layer in a non-oxidizing atmosphere, permitting a solid-phase growth to take place in a region containing no nitrogen while remaining the nitrogen-containing surface region as an amorphous insulating layer, thereby forming an epitaxial crystalline insulating layer containing a metal, silicon and oxygen on the substrate side of the amorphous insulating layer.

8. The method of manufacturing a semiconductor device according to claim 7, wherein the nitrogen is contained in the surface region of the amorphous insulating layer at a concentration of 15 atom % or more.

9. The method of manufacturing a semiconductor device according to claim 7, wherein the metal includes at least one element selected from the group consisting of Zr, Hf, Ti and lanthanoid elements.

10. The method of manufacturing a semiconductor device according to claim 7, wherein the surface region containing nitrogen has a thickness ranging from 1 nm to 2.5 nm.

11. The method of manufacturing a semiconductor device according to claim 7, wherein the amorphous insulating layer containing nitrogen in the surface region thereof is formed by depositing a metal silicate film on the substrate and exposing the metal silicate film to exited nitrogen.

12. The method of manufacturing a semiconductor device according to claim 11, wherein the metal silicate film has a thickness of 10 nm or less.

13. The method of manufacturing a semiconductor device according to claim 7, wherein the amorphous insulating layer containing nitrogen in the surface region thereof is formed by depositing a metal silicate on the substrate in a nitrogen atmosphere.

14. The method of manufacturing a semiconductor device according to claim 13, wherein the metal silicate film has a thickness of 10 nm or less.

15. The method of manufacturing a semiconductor device according to claim 7, wherein the non-oxidizing atmosphere is an atmosphere containing oxygen at a partial pressure of 1×10⁻³ Torr or less.

16. The method of manufacturing a semiconductor device according to claim 7, further comprising forming an electrode on the amorphous insulating film successively forming the amorphous insulating film.

17. The method of manufacturing a semiconductor device according to claim 7, wherein the heat treatment is performed at a temperature ranging from 950° C. to 1200° C.

18. A method of manufacturing a semiconductor device comprising:
forming an amorphous insulating layer containing metal, silicon and oxygen on a substrate, the amorphous insulating layer comprising a surface region and a substrate side remnant region, the surface region further containing a nitrogen of a first concentration, and the remnant region containing a nitrogen of a second concentration less than the first concentration; and
heat-treating the amorphous insulating layer in a non-oxidizing atmosphere, permitting a solid-phase growth to take place in the substrate remnant region while having the first region as an amorphous insulating layer.

19. The method of manufacturing a semiconductor device according to claim 18, wherein the non-oxidizing atmosphere comprises a partial oxygen pressure of 1×10⁻³ Torr or less.

20. The method of manufacturing a semiconductor device according to claim 18, wherein the non-oxidizing atmosphere is formed by depositing a conductive film on the amorphous insulating prior to the step of heat-treating.

21. The method of manufacturing a semiconductor device according to claim 18, wherein the metal includes at least one element selected from the group consisting of Zr, Hf, Ti and lanthanoid elements.
